(19) United States
(12) Patent Application Publication
(10) Pub. No.: US 2009/0189261 A1
(43) Pub. Date: Jul. 30, 2009

(54) Ultra-Thin Semiconductor Package

(76) Inventors: Lay Yeap Lim, Gelugor (MY); David Chong, Bayan Leaps (MY)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/020,286

(22) Filed: Jan. 25, 2008

(51) Int. Cl. H01L 23/495; H01L 21/50

(52) U.S. Cl. 257/676; 438/123; 257/E23.037; 257/E21.499

(57) ABSTRACT

Semiconductor packages with a reduced-height die pad and associated methods for making and using these semiconductor packages are described. The semiconductor packages include a lead frame with die pad of reduced height so the die pad has a height that is less than that of the lead frame. The semiconductor packages may comprise an isolated and/or a fused lead finger with a portion of an upper surface of the isolated lead finger that is removed to form a concavity to which one or more bond wires may be bonded. The upper surface of the isolated lead finger may be removed so the isolated lead finger has a height that is less than the height of the lead frame. And a perimeter of a bottom surface of the fused lead finger may be removed. Other embodiments are described.

### FIELD

This application relates generally to packaged semiconductor devices or semiconductor packages. More specifically, this application relates to thin semiconductor packages with a reduced-height die pad and associated methods for making and using the semiconductor package.

### BACKGROUND

Semiconductor packages are well known in the art. Generally, these packages may include one or more semiconductor devices, such as an integrated circuit die or chip, which may be connected to a die pad that is centrally formed in a lead frame. In some cases, bond wires electrically connect the integrated circuit die to a series of lead fingers that serve as an electrical connection to an external device (such as a printed circuit board (“PCB”)). An encapsulating material covers the bond wires, integrated circuit die, lead fingers, and other components of the semiconductor device to form the exterior of the semiconductor package. A portion of the lead fingers and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package may be used in an ever growing variety of electronic applications, such as disk drives, USB controllers, portable computer devices, cellular phones, and so forth. Depending on the die and the application, the semiconductor package may be highly miniaturized and may need to become thin as possible. These smaller and/or thinner semiconductor packages may be referred to as micro lead frame packages (“MLPs”).

Most conventional MLPs, however, may use a buildup substrate to form part the lead frame. Because buildup substrates cost more than standard lead frame base materials, MLPs implementing buildup substrates may be expensive to produce. As well, some conventional MLPs may require bond on stitch ball (“BSOB”) wire bonding to achieve low wire looping and reduce the height of the package. However, BSOB wire bonding can be slow and difficult to perform, the high stress of the BSOB ball bumping process may induce bond catering (where a portion of the die is torn loose), and BSOB may be not produce uniformly shaped balls. Further, the die pad of some MLPs may have a cavity formed in the die pad with a wall around the perimeter of the die pad that prevents epoxy from flowing off of the die pad. And this cavity wall radius both limits the size of a die that can fit on the die pad and causes the die to tilt and not seat properly against the die pad during die attachment.

### SUMMARY

This application relates to semiconductor packages with a reduced-height die pad and associated methods for making and using these semiconductor packages. The semiconductor packages include a lead frame with die pad of reduced height so the die pad has a height that is less than that of the lead frame. The semiconductor packages may comprise an isolated and/or a fused lead finger with a portion of an upper surface of the isolated lead finger that is removed to form a concavity to which one or more bond wires may be bonded. The upper surface of the isolated lead finger may be removed so the isolated lead finger has a height that is less than the height of the lead frame. And a perimeter of a bottom surface of the fused lead finger may be removed.

### BRIEF DESCRIPTION OF THE DRAWINGS

The following description can be better understood in light of the Figures, in which:

FIG. 1 contains a view of some embodiments of a thin semiconductor package;

FIGS. 2a and 2b each contain a different view of some embodiments of a lead frame with integrated circuit dies;

FIG. 3a contains a view of some embodiments of a thin semiconductor package;

FIG. 3b contains a table depicting examples of material thicknesses in a thin semiconductor package;

FIGS. 4a and 4b each contain a view of some embodiments of a thin semiconductor package before encapsulation;

FIG. 5 shows a cross-sectional view of some embodiments of an etched lead frame; and

FIG. 6 depicts a comparison between some embodiments of a thin semiconductor package and a conventional semiconductor package.

The Figures illustrate specific aspects of the semiconductor packages and associated methods of making and using such packages. Together with the following description, the Figures demonstrate and explain the principles of the semiconductor packages and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and methods for making and using such packages can be implemented and used without employing these specific details. For example, while the detailed description focuses on semiconductor packages that are less than about 0.4 millimeters thick, the described semiconductor packages may have any desired thickness. Furthermore, while the following description focuses on thin semiconductor packages, such as MLP packages, quad MLPs (“MLPQs”), micro MLPs (“MLPMs”), and dual MLPs (“MLPDs”), the described methods and techniques may be used with any other suitable type of semiconductor package.

The Figures illustrate some embodiments of a thin semiconductor package with a reduced-height die pad. In some embodiments, the semiconductor packages can be ultra-thin since they can have a thickness less than about 0.4 millimeters. In other embodiments, the semiconductor packages can have a thickness less than about ______ millimeters.

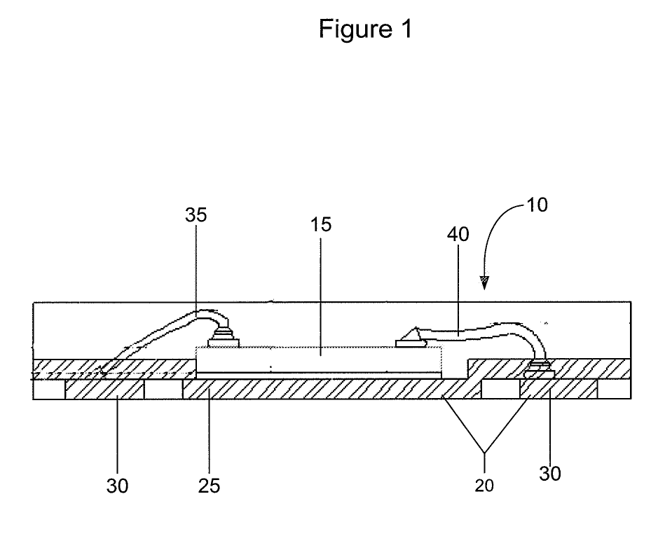

The Figures show some embodiments of ultra-thin semiconductor packages. FIG. 1 shows an ultra-thin semiconductor package 10 that comprises an integrated circuit die 15 (or die), a lead frame 20 that comprises a reduced-height die pad 25 and a lead finger (e.g., lead finger 30), a bond wire (e.g., wires 35 and 40), and an encapsulation material (not shown). The semiconductor package 10 may also contain any other known component contained in semiconductor packages, including, but not limited to, tie bars and dam bars.

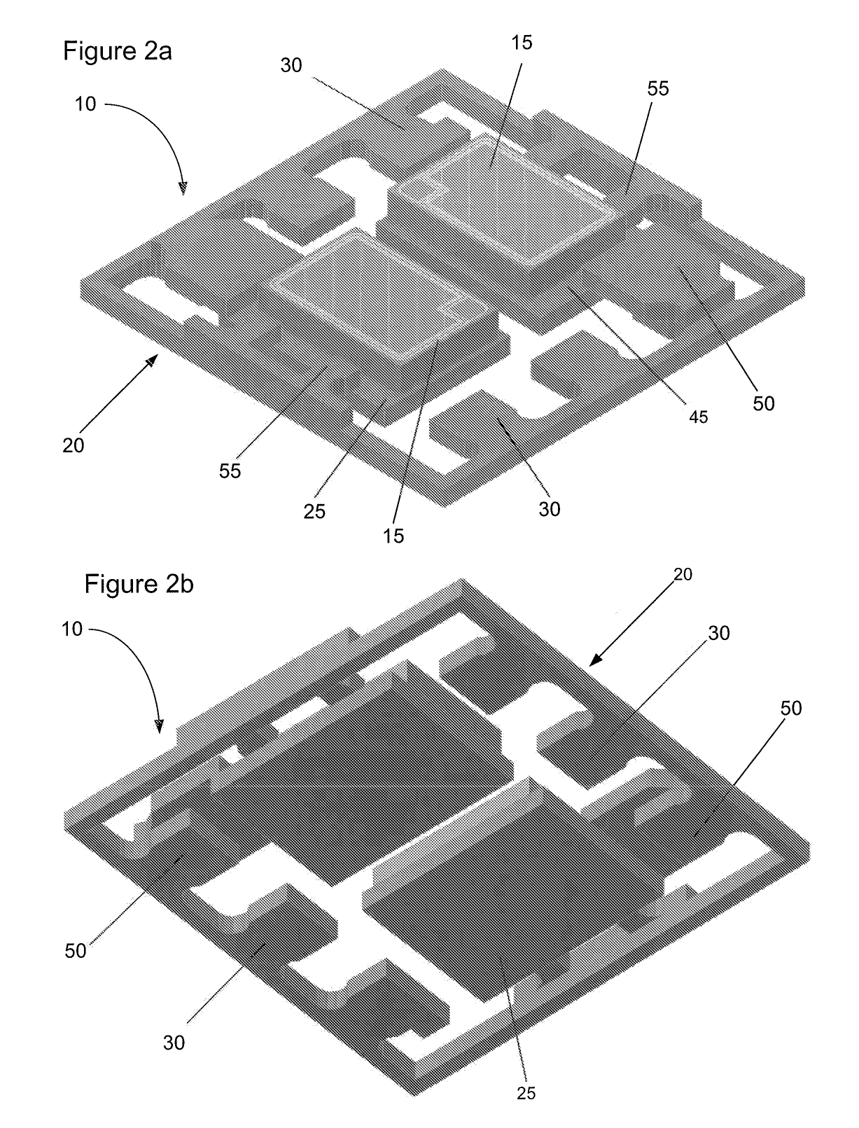

The semiconductor package 10 may comprise a die. Indeed, the semiconductor package 10 may comprise any number of dies known in the art. For example, FIG. 2a shows some embodiments of a partially assembled semiconductor package 10 containing 2 dies 15. In other examples, however, the package 10 could contain less (i.e., 1 die) or more (i.e., 3 or more dies).

The die 15 may be any known die that can be used in a semiconductor package. FIG. 1 shows the die 15 may include an upper surface. In some embodiments, the upper surface of the die 15 may comprise a plurality of input and/or output bond pads (not illustrated) that make the upper surface of the die available for electrical connection. Additionally, the die 15 may comprise a lower surface that may rest on and/or be attached to a die pad 25.

The die 15 may be made of any suitable semiconductor material. Some non-limiting examples of semiconductor materials may include silicon, polysilicon, gallium arsenide, silicon carbide, gallium nitride, silicon and germanium, and the like. Similarly, the die 15 may contain any suitable integrated circuit or semiconductor device. Some non-limiting examples of these devices may include diodes and transistors, including bipolar junction transistors (“BJT”), metal-oxide-semiconductor field-effect transistors (“MOSFET”), and insulated-gate field-effect transistors (“IGFET”).

FIGS. 2a and 2b depict that, in some embodiments, the semiconductor package 10 may comprise a lead frame 20. The lead frame 20 may support the die 15, serve as part of the I/O interconnection system, and may provide a thermally conductive path for dissipating heat generated by the die 15. The lead frame 20 may have any characteristic or feature consistent with these functions. For example, the lead frame 20 may be made from any lead frame material, including a buildup substrate or standard lead frame base materials, like copper, Alloy 42, or a copper alloy. Because standard lead frame base materials may be less expensive than buildup substrates, some embodiments of the lead frame 20 comprise standard lead frame materials.

The lead frame 20, in some instances, may contain a layer of metal plating (not shown). The layer of metal plating may comprise NiPdAu, an adhesion sublayer, a conductive sublayer, and/or an oxidation resistant layer. For example, the lead frame 20 may include plating containing an adhesion sublayer and a wettable/protective sublayer. The leadframe surface will be roughened either by plating or to increase the locking between the mold compound and the die-attach epoxy. Additionally, the lead frame 20 may be electroplated or otherwise coated with a layer of a solderable conductive material, such as tin, gold, lead, silver, and/or another solderable material.

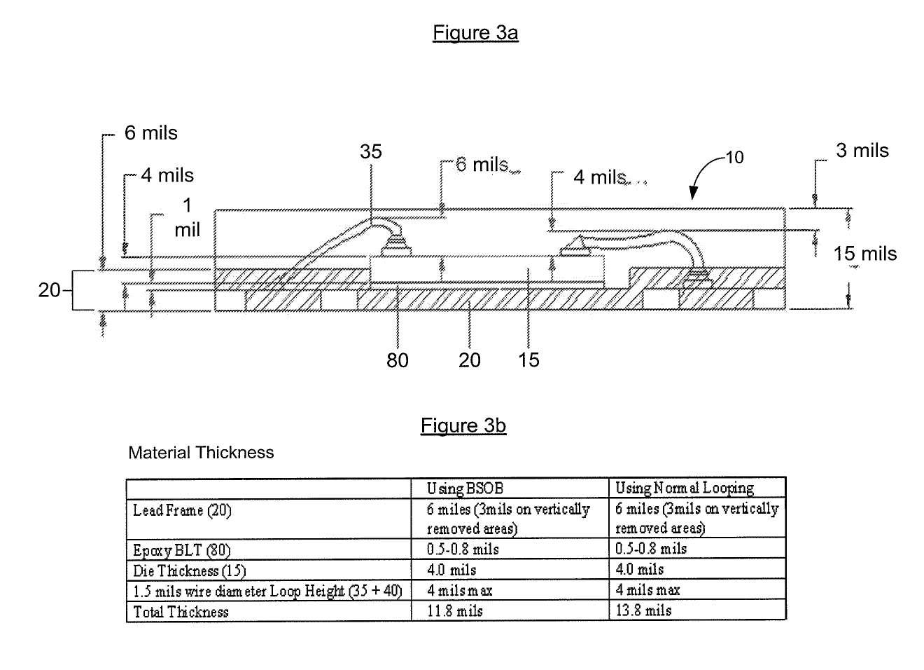

The lead frame 20 may have any height that allows it to be used in the semiconductor packages described herein. For instance, the lead frame 20, as measured from the bottom surface of the frame to the upper surface of the frame or leads (which ever is higher) may be as thick as about 10 mils, or 1/100 of an inch. However, in other embodiments, the lead frame 20 may be as thin as about 2 and about 10 mils thick or about half the starting leadframe 20 thickness. FIG. 3a and the table in FIG. 3b show that, according to some embodiments, the lead frame 20 may have a height, or thickness, of about 6 mils.

The lead frame 20 may comprise a reduced-height die pad 25, or die pad 25. Indeed, according to some aspects, the lead frame 20 may comprise a die pad 25 for every die 15 that is contained in the package 10. For example, FIG. 2a shows the lead frame 20 may comprise 2 die pads 25 to which 2 dies 15 may be attached.

The die pad 25 may have any characteristic that allows the die 15 to be attached to it while allowing the semiconductor package 10 to be less than or equal to the desired thickness. For instance, the die pad 25 may comprise an upper surface to which the die 15 may be attached. In some embodiments, a substantial portion of the upper surface of the die pad 25 may be removed to reduce the height of the die pad 25 below the height of the lead frame 20. By way of example, FIGS. 2a and 3a show embodiments where the upper surface of the die pad 25 has been vertically removed. FIGS. 2a and 3a show the remaining upper surface 45 of the die pad 25 may be substantially planar, except where the fused lead fingers 50 and tie bars 55 (both of which are described below) contact the die pad 25.

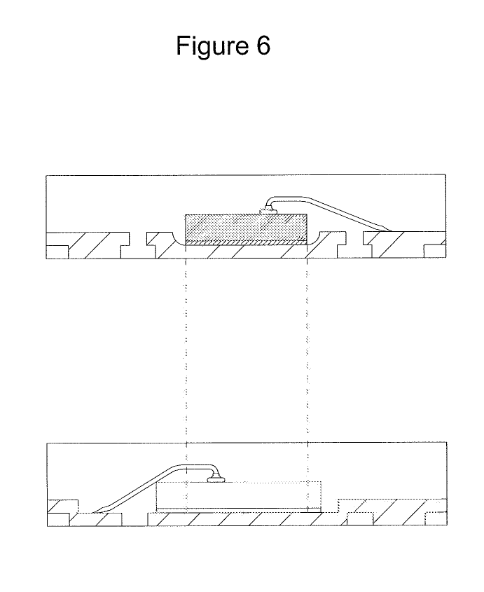

FIG. 2a illustrates some embodiments where the upper surface 45 of the die pad 25 is removed. In these embodiments, the remaining upper surface 45 of the die pad 25 may be substantially planar so as not to have cavity radius walls (not shown) (e.g., un-removed portions of the die pad that are disposed at the perimeter of the die pad and are raised above the remaining substantially planar upper surface of the die pad). In other words, the die pad 25 in FIG. 2a is wallless. Without walls, the upper surface 45 of the die pad 25 may be larger than that of some conventional die pads that have cavity radius walls. Accordingly, the described die pad 25 may accommodate larger die sizes than may some conventional die pads. For example, the die size will increase by an area equivalent to the area need to build an anchor for the die pad, as illustrated in FIG. 6.

Where a portion of the upper surface of the die pad 25 is removed, the height of the die pad 25 may be reduced from the height of the lead frame 20 to any desired height. In some embodiments, the upper surface of the die pad may be vertically removed so that every upper surface of the die pad has a height that is less than the height of the lead frame 20. For example, FIG. 3a shows the die pad 25 may be vertically reduced so as to have a height that is about half the height of the lead frame 20. Specifically, FIG. 3a and the table in 3b show that, in some embodiments where the lead frame 20 has a height of approximately 6 mils, the height of the die pad 25 may be reduced to approximately half the height of the lead frame 20, or about 3 mils. Nevertheless, in other embodiments, the upper surface 45 of the die pad 25 may be vertically removed so as to have a height that is greater than or less than ½ the height of the lead frame 20.

The lead frame 20 may comprise at least one lead finger. The lead finger may provide an interface to electrically and/or mechanically connect the semiconductor package 10 to an external device, such as a PCB. As shown in FIG. 2a, lead fingers (e.g., lead fingers 30 and 50) may be formed at regular (or non-regular) intervals on the perimeter of the lead frame 20 so as to extend towards the die pad 25. For instance, the lead fingers may be formed at regular intervals on two or four edges of the lead frame 20.

The lead frame 20 may comprise any suitable type of lead finger. For example, the lead frame 20 may comprise an input lead finger (a lead finger that is electrically connected to an input bond pad on the die) or an output lead finger (a lead finger that is electrically connected to an output bond pad of the die). The number of lead fingers can be any number known in the art.

In some embodiments, the lead frame may contain an isolated lead finger and a fused lead finger. FIGS. 2a and 2b illustrate that the lead frame 20 may comprise at least one isolated lead finger 30 that need not be mechanically attached to the die pad 25. FIGS. 2a and 2b also show the lead frame 20 may also comprise at least one fused lead finger 50 that may be mechanically attached to the die pad 25.

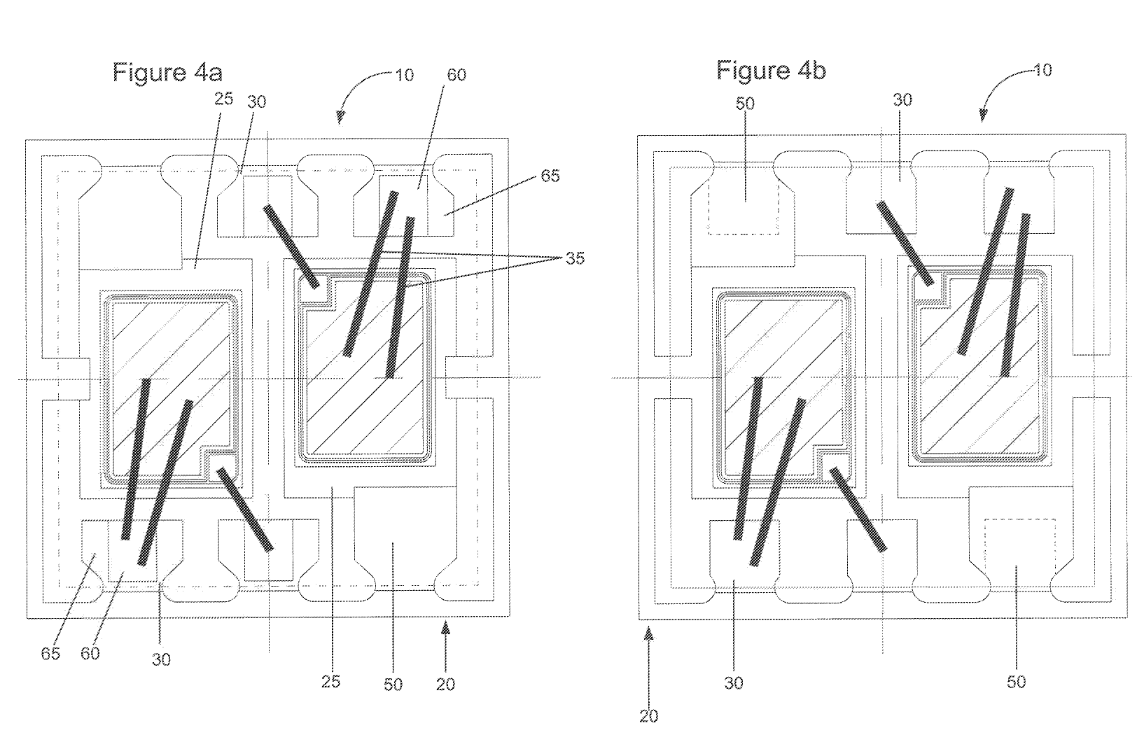

The isolated lead finger 30 may have any characteristic suitable for use in a semiconductor package. For example, the isolated lead finger 30 may have any suitable width. FIGS. 4a and 4b illustrate embodiments of the semiconductor package 10 where the isolated lead fingers 30 have different widths. Specifically, the isolated lead fingers 30 in FIG. 4a are wider than the isolated lead fingers 30 that are illustrated in FIG. 4b.

In some embodiments, portions of the isolated lead fingers 30 may be removed to accommodate bond wires of differing sizes or lead fingers of differing widths. FIG. 4a shows embodiments of the isolated lead fingers 30 where a portion of the upper surface is removed to create a concavity 60. The concavity 60 can have any characteristic that allows for an electronic connection (e.g., permits wires 35 and/or 40 to be bonded to it). Thus, the concavity 60 may extend to and open from the edge of the isolated lead finger 30 that is closest to the die pad 25. The concavity 60 may have any desired shape, including a round, or substantially square or rectangular shape, as shown in FIG. 4a. The concavity 60 may have any depth, including a depth that is more than, less than, or equal to half the lead frame height.

The concavity 60 may allow the upper surface of the isolated lead finger 30 to contain a metal area 65. Such a metal area 65 may not have been removed or has not been removed to the extent of the concavity 60. The isolated lead finger 30 at the metal area 65 may have a height that is greater than or less than the height of the lead frame 20. In some embodiments, though, the metal area 65 of the isolated lead finger 30 has a height that is about equal to the height of the lead frame 20. For example, where the lead frame 20 has a height of about 6 mils, the isolated lead finger 30, as measured from the upper surface of the metal area 65 to the lower surface of the lead finger 30, may have a height of about 6 mils.

FIGS. 4b (and 2a) shows embodiments where the upper surface of the isolated lead finger 30 has been removed to reduce the height of the isolated lead finger 30. The height of the isolated lead fingers 30 may be reduced to any height that allows the upper surface to be available for electrical connection. For example, the isolated lead finger 30 may be reduced to have a height that is less than, greater than, or about equal to half the height of the lead frame 20. In some examples, however, the isolated lead finger 30 may be reduced to have a height that is about equal to half the height of the lead frame 20. For instance, where the height of the lead frame 20 is about 6 mils, the upper surface of the isolated lead fingers 30 may be removed so the isolated lead fingers 30 have a height that is equal to about 3 mils.

The fused lead finger 50 may also have any characteristic suitable for use with a semiconductor package. For example, the fused lead finger 50 may be any size suitable for use in a semiconductor package. FIG. 4a shows some embodiments where the fused lead finger 50 is wider than the isolated lead finger 30. Moreover, FIG. 4b shows some embodiments where the upper surface of the fused lead finger 50 is larger (e.g., wider and longer) than the lower surface (depicted by dotted lines) of the fused lead finger 50.

In some embodiments, the fused lead finger 50 may be substantially unmodified or may have portions removed. FIG. 4a illustrates embodiments of the fused lead finger 50 that have not had portions removed. In FIG. 4a, the fused lead finger 50 may have a height that is substantially equal to the height of the lead frame 20. Also, the lack of dotted lines in FIG. 4a shows that the upper surface of the fused lead finger 50 may have a similar shape and size to the finger's bottom surface.

FIGS. 4b (and 2b) illustrates other embodiments of the fused lead finger 50 where a portion of the fingers' bottom surface has been removed. Any desired amount of the bottom of the fused lead finger 50 may be removed. For instance, a portion of a perimeter of the bottom surface of the fused lead finger 50 may be removed as shown by the dotted lines on the fused lead fingers 50 in FIG. 4b. In this example, enough of the bottom of the fused lead fingers 50 has been removed so that—at least from a bottom view of an encapsulated semiconductor package—the fused lead fingers 50 appears to be isolated from the die pad 25. With portions removed, the bottom surface may have any desired shape or size known in the art, including a shape and size that are similar to the isolated lead fingers 30, as shown in FIG. 2b.

The lead frame 20 may comprise any combination of isolated 30 and/or fused 50 lead fingers with any of these features. For example, FIG. 4a shows one lead frame 20 comprising both wide isolated lead fingers 30 with a concavity 60 and fused lead fingers 50 that have not had portions removed. Such a lead frame may be especially useful with smaller diameter bond wires (e.g., wires with a diameter less than or equal to about 1.5 mils) and/or lead frames with wider lead fingers. In another example, FIG. 4b shows another lead frame 20 comprising both fused lead fingers 50 that have a portion of their bottom surface removed as well as narrow isolated lead fingers 30 with a reduced height. Such a lead frame may especially useful with thicker diameter wires (e.g., wires with a diameter greater than or equal to about 1.5 mils). In yet another example, the lead frame 20 may comprise isolated lead fingers 30 that have the concavity 60 as well as fused lead fingers 50 that have a portion of the perimeter of the bottom surface removed. In still another example, the lead frame 20 may comprise isolated lead fingers 30 that contain a concavity as well as isolated lead fingers 30 that have been reduced in height over the entire upper surface. In still yet another example, the lead frame 20 may comprise fused lead fingers 50 that have not had portions removed from them as well as fused lead fingers 50 that have had a portion of the lower surface removed.

In addition to these configurations, the lead fingers (e.g., the isolated 30 and/or the fused 50 lead fingers) may be also be modified as known in the art. In these embodiments, the upper surface of the isolated lead fingers may be electroplated with a conductive material, such as silver, lead, aluminum, or gold to improve the electrical connection between the lead fingers and the die 15.

The lead fingers may be electrically connected to one or more dies through any manner known in the art. For example, the die 15 may be electrically connected to at least one isolated lead finger 30 by wire bonding; ribbon bonding; solder bumps, balls, or studs; and/or other methods. FIG. 1 shows bond wires 35 and 40 that may electrically connect the die 15 isolated lead fingers 30. Where bond wires are used to electrically connect the isolated lead fingers 30 to the die 15, the bond wires may be made from any conductive material, including gold, silver, platinum, copper, copper alloys, etc. . . . The bond wires 35 and 40 may be electrically connected to the lead fingers and bond pads through any known technique, including standard looping wire bonding, BSOB wire bonding, trapezoidal type looping via known bonding methods such as thermocompression bonding, ultrasonic bonding or thermo-sonic bonding. For example, FIG. 1 illustrates that where the diameter of the bond wire 35 is less than about 1.5 mils, the bond wire 35 may be bonded to the isolated lead finger 30 and/or die 15 through standard looping wire bonding. In another example, FIG. 3a illustrates that BSOB wire bonding may be used to bond the wire 40 to the isolated lead finger 30 and the die 15. This example shows that loops with a low profile may still be achieved, even with wires that have a diameter equal to or greater than about 1.5 mils.

BSOB wire bonding may be performed in any known manner. For example, a ball bump made from an electrically conductive material, such as gold, may be used to bond one end of the wire 40 to a bond pad located on the die 15. Another conductive ball located at the other end of the wire 40 may be bonded to an isolated lead finger 30 by using ultrasonic energy. Following the bonding with ultrasonic energy, a wedge bonding process may be performed on top of one or more of the conductive bumps.

FIGS. 3a and 3b show a non-limiting example of the semiconductor package 10 wherein bond wires are bonded by standard loop wire bonding and BSOB wire bonding. Indeed, those Figures show the arc of a loop of bond wire 35 that has been bonded though standard loop wire bonding may give the package 10 a total height of about 13.8 mils, before encapsulation. If, however, the bond wire were to have a diameter larger than about 1.5 mils, the total height of the semiconductor package 10 before encapsulation may be increased above 13.8 mils. Thus, in such embodiments, it may be beneficial to use BSOB wire bonding to prevent the package 10 from having an undesirable height.

FIGS. 3a and 3b also show how BSOB wire bonding may reduce the height of the semiconductor package 10 before encapsulation so as to accommodate larger bond wires. FIG. 3a shows that where a bond wire 40 is bonded through BSOB wire bonding, the total height of the semiconductor package 10 before encapsulation may be about 11.8 mils, or about 2 mils shorter than if standard wire looping were used. However, because BSOB wire bonding may be more expensive than standard wire loop bonding, in some cases, standard wire loop bonding may be used for wires with a diameter of less than or equal to about 1.5 mils.

In addition to these components, the semiconductor package 10 may comprise other known semiconductor package components. For instance, FIG. 2a shows the lead frame 20 may include tie bars 55, as are known in the art. The semiconductor package 10 may include any number of tie bars 19 with any desired feature. For example, FIG. 2a shows the lead frame 20 may comprise a plurality of tie bars 55 that extend from the die pads 25 towards the outer perimeter of the lead frame 20.

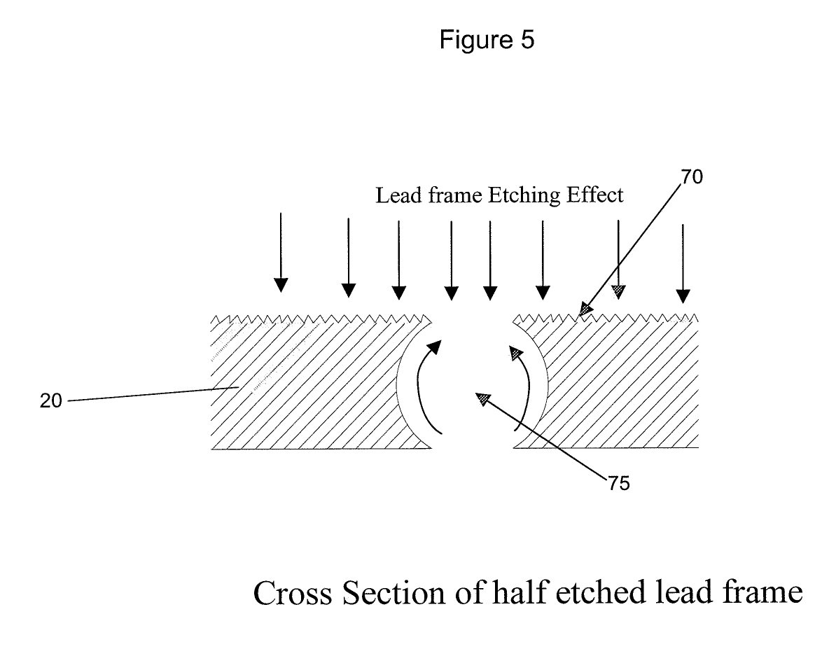

Although not shown in the Figures, the die 15, die pad 25, lead finger (e.g., lead fingers 30 and 50), bond wires 35 and 40, and/or any other desired component may be encapsulated in a suitable encapsulation or molding material. Some non-limiting examples of suitable molding materials may include thermoset resins—such as silicones, phenolics, and epoxies—and thermoplastics. Moreover, the molding material may be formed around portions of the desired components as known in the art, including by injection of the encapsulation material, transfer molding, and/or other appropriate methods.

Where the upper portion of the die pad 25 and/or portions of one or more of the lead fingers are removed, the molding compound may be anchored to the lead frame 20. For example, FIG. 5 shows that where one side of the lead frame 20 is removed through etching, the etching may roughen the etched side to create a rough surface 70. The rough surface 70 may enhance the adhesion between the lead frame 20 and the molding compound. FIG. 5 also shows that a natural effect of the etching may cause a curve 75 to be formed in etched portions of the lead frame 20. Such a curve 75 may serve to lock molding compound in the middle of the lead frame material.

The semiconductor package 10, including any of its components, may be manufactured by any suitable method, including the following processes. First, the lead frame 20 (containing the die pad 25 and the lead fingers 30 and 50) may be made by any known process such as drawing and rolling of the metal into foil. The desired portions of the die pad, isolated, and/or fused lead fingers may then be removed through any known or novel method, such as through patterning and/or chemical etching.

The die 15 may then be attached to the die pad 25. This process can be performed using any technique known in the art, such as a conventional die flipping processes. During this process, the lower surface of the die 15 may be connected to the upper surface 45 of the die pad 25 by, for example, using a non-conductive chemical adhesive or epoxy, a mechanical connection (e.g., a conventional clip), a solder, a conductive adhesive (e.g., PbSn solder paste, silver epoxy, etc), a screen printed conductive or non-conductive epoxy, and/or a die attach film (“DAF”). In some embodiments, screen printed epoxy or DAF are used because epoxy overflow may be avoided. As well, these two methods allow for a thin bond line thickness (“BLT”) between the die 15 and the die pad 25. For example, FIG. 3a and the table in FIG. 3b show an epoxy BLT 80 may be between about 0.5 and about 0.8 mils. Nevertheless, the BLT may be thicker or thinner in other embodiments.

Following die 15 attachment, the bonds wires may be provided to connect the die 15 to the lead fingers (e.g., isolated lead fingers 30) using any known process, including those already described. Following the attachment of the bond wires, a molding material may then be provided to encapsulate the components as known in the art.

Once these processes are performed, the semiconductor packages may be singulated as known in the art. For example, the dotted lines in FIG. 4a illustrate that excess material may be removed from the package 10 during singulation. Some non-limiting examples of methods for singulation may include saw singulation or punch singulation. The singulated semiconductor package 10 may then be electrically tested. After electrical testing, the molding material in the semiconductor package 10 may be laser marked. Finally, the semiconductor package 10 may be taped and reeled as known in the art.

The semiconductor package 10 may be used in any suitable electronic apparatus or device known in the art. In some non-limiting examples, the semiconductor package 10 may be used in any type of electronic device, including those mentioned above, as well as logic or analog devices.

The semiconductor package 10 may offer several advantages. First, as explained, the semiconductor package 10 may use standard lead frame base materials. These standard materials may be less expensive than buildup substrates. Accordingly, the semiconductor package 10 may provide a lower cost option than semiconductor packages that use a buildup substrate to create a package with a low profile. Second, because the semiconductor package 10 may use standard lead frame base materials, the package 10 may be manufactured in a manner that is substantially similar to standard MLP flow processes. Thus, the semiconductor package 10 may be produced without requiring costly changes to the current MLP process flow. Third, the semiconductor package 10 does not need expensive BSOB wire bonding to achieve low wire looping because the upper surface 45 of the die pad 25 and portions of the lead fingers may be removed, allowing the semiconductor package 10 to use less expensive standard wire looping to achieve low loops for wires having a diameter of less than or equal to about 1.5 mil.

A fourth advantage is that the semiconductor package 10 may allow for a larger die 15 than other low profile semiconductor packages. Because the upper surface 45 of the die pad 25 may be removed without forming a cavity, the die pad 25 is substantially planar and wall-less (e.g., has no cavity radius walls). Thus, the semiconductor package 10 may allow for a larger die than some semiconductor packages containing a cavity in the die pad. Also, because the die pad 25 may not have cavity radius walls, the die 15 may not be as prone to tilt during die placement.

A fifth advantage is that the footprint of the semiconductor package 10 may be similar to the footprint of standard lead frame design semiconductor packages. The footprint of the semiconductor package 10 can be the same as that of a conventional MLP since the fused area of the fused lead fingers 50 is embedded in the molding compound. Accordingly, the semiconductor package 10 may be used in many of the same applications in which conventional semiconductor packages are used.

Having described the preferred aspects of the semiconductor package and associated methods, it is understood that the appended claims are not to be limited by particular details set forth in the description presented above, as many apparent variations thereof are possible without departing from the spirit or scope thereof.

1. An ultra-thin semiconductor package, comprising:
a lead frame containing a die pad and an isolated lead finger, wherein the height of the die pad is less than the height of the lead frame and the die pad does not contain a cavity in the upper surface; and
a die attached to the upper surface die pad.

2. The semiconductor package of claim 1, wherein the lead frame further comprises a fused lead finger.

3. The semiconductor package of claim 1, wherein a portion of an upper surface of the isolated lead finger is removed to create a concavity adapted to be bonded with a bond wire.

4. The semiconductor package of claim 1, wherein an upper surface of the isolated lead finger is removed so the isolated lead finger has a height less than the height of the lead frame.

5. The semiconductor package of claim 2, wherein a portion of a perimeter of a bottom surface of the fused lead finger is removed.

6. The semiconductor package of claim 1, wherein a bond wire with a diameter less than or equal to about 1.5 mils electrically connects the die to the isolated lead finger through standard looping wire bonding.

7. The semiconductor package of claim 1, wherein a bond wire with a diameter greater than or equal to about 1.5 mils electrically connects the integrated circuit die to the isolated lead finger through bond on stitch ball wire bonding.

8. An ultra-thin semiconductor package, comprising:
a lead frame containing a die pad, a fused lead finger, and an isolated lead finger, wherein the height of the die pad is less than the height of the lead frame and the die pad does not contain a cavity in the upper surface; and
a die attached to the upper surface die pad.

9. The semiconductor package of claim 8, wherein a portion of an upper surface of the isolated lead finger is removed to create a concavity adapted to be bonded with a bond wire.

10. The semiconductor package of claim 8, wherein an upper surface of the isolated lead finger is removed so the isolated lead finger has a height less than the height of the lead frame.

11. The semiconductor package of claim 10, wherein a portion of a perimeter of a bottom surface of the fused lead finger is removed.

12. The semiconductor package of claim 8, wherein a bond wire with a diameter less than or equal to about 1.5 mils electrically connects the die to the isolated lead finger through standard looping wire bonding.

13. The semiconductor package of claim 8, wherein a bond wire with a diameter greater than or equal to about 1.5 mils electrically connects the integrated circuit die to the isolated lead finger through bond on stitch ball wire bonding.

14. An electronic apparatus containing an ultra-thin semiconductor package, the ultra-thin semiconductor package comprising:
a lead frame containing a die pad, a fused lead finger, and an isolated lead finger, wherein the height of the die pad is less than the height of the lead frame and the die pad does not contain a cavity in the upper surface; and
a die attached to the upper surface die pad; and
an electrical device containing a surface to which the isolated lead finger is connected.

15. The apparatus of claim 14, wherein a portion of an upper surface of the isolated lead finger is removed to create a concavity adapted to be bonded with a bond wire

16. The apparatus of claim 14, wherein an upper surface of the isolated lead finger is removed so the isolated lead finger has a height less than the height of the lead frame

17. The apparatus of claim 16, wherein a portion of a perimeter of a bottom surface of the fused lead finger is removed.

18. The apparatus of claim 14, wherein a bond wire with a diameter less than or equal to about 1.5 mils electrically connects the die to the isolated lead finger through standard looping wire bonding.

19. The apparatus of claim 14, wherein a bond wire with a diameter greater than or equal to about 1.5 mils electrically connects the integrated circuit die to the isolated lead finger through bond on stitch ball wire bonding.

20. A method of making an ultra-thin semiconductor package, comprising:
providing a die;
providing a lead frame containing a die pad, a fused lead finger, and an isolated lead finger;
removing an upper surface of the die pad so that height of the die pad is less than the height of the lead frame and the die pad does not contain a cavity in its upper surface;
attaching the die to the die pad; and
electrically connecting the isolated lead finger to the die.

21. The method of claim 20, wherein a portion of an upper surface of the isolated lead finger is removed to create a concavity adapted to be bonded to a bond wire.

22. The method of claim 20, wherein an upper surface of the isolated lead finger is removed so the isolated lead finger has a height that is less than the height of the lead frame.

23. The method of claim 22, wherein a portion of a perimeter of a bottom surface of the fused lead finger is removed.

24. The method of claim 20, wherein a bond wire with a diameter less than or equal to about 1.5 mils electrically connects the integrated circuit die to the isolated lead finger through standard looping wire bonding.

25. The method of claim 20, wherein a bond wire with a diameter greater than or equal to about 1.5 mils electrically connects the integrated circuit die to the isolated lead finger through bond on stitch ball wire bonding.
